(19) United States
(12) Patent Application Publication
(10) Pub. No.: US 2007/0284081 A1
(43) Pub. Date: Dec. 13, 2007

(54) Heatsink device having fiber-like fins

(76) Inventor: Han-Ming Lee, Hsin Chu City (TW)

Correspondence Address: Han-Ming Lee, P.O. BOX 7-820, HSIN CHU CITY, TAIPEI, omitted

(21) Appl. No.: 11/438,784

(22) Filed: May 24, 2006

(51) Int. Cl. H05K 7/20

(52) U.S. Cl. 165/80.3; 361/704

(57) ABSTRACT

A heatsink device is provided herein, which mainly contains a larger number of pins made of highly thermal conducting material into fiber-like linear segments. The fiber-like fins have one of their ends inserted into tubular holders which are fused or welded together into a planar base, or into the holes on the top surface of a planar base. The fiber-like fins therefore extend upward with appropriate spacing among them, and can be further woven into webs.

### BACKGROUND OF THE INVENTION

(A) Field of the Invention

The present invention generally relates to heatsink device for IC chips, and more particularly to a heatsink device having a large number of fiber-like fins.

(B) Description of the Prior Art

IC chips are the most important components in computers and various electronic appliances, and they are more producing more heat than before as they are driven by faster clocks and more functionality is integrated. This heat, without proper dissipation, would reduce the operation life of the chip if the chip is not damaged in the first place. The neighboring electronic components are often affected by the heat as well. Most of the IC chips are therefore used along with heatsink devices usually manufactured by aluminum extrusion. The conventional aluminum-made heatsink devices is bulky and provides limited heat dissipation capability so that an auxiliary fan is usually required to driver cool air through the heatsink device, therefore talking up even more space. For today's appliances and computers which are driver by market demands for even smaller form factors and more appealing outlook, the inflexibility of conventional heatsink devices has become a major and serious obstacle to overcome.

### SUMMARY OF THE INVENTION

The primary purpose of the present invention is to provide a heatsink device, which mainly contains a larger number of fins made of highly thermal conducting material into fiber-like linear segments. The fiber-like fins have one of their ends inserted into tubular holders which are fused or weld together to form a planar base, or into the holes on the top surface of a planar base. The fiber-like fins therefore extend upward with appropriate spacing among them.

The present invention offers a number of advantages. First, the fiber-like fins significantly increase the heatsink device's contact area with air for superior heat dissipation efficiency. Secondly, the fiber-like fins can be easily manipulated and woven into webs to fit limited or irregular interior space of various electronic appliances without sacrificing the heat dissipation efficiency.

The foregoing object and summary provide only a brief introduction to the present invention. To fully appreciate these and other object of the present invention as well as the invention itself, all of which will become apparent to those skilled in the art, the following detailed description of the invention and the claims should be read in conjunction with the accompanying drawings. Throughout the specification and drawing identical reference numerals refer to identical or similar parts.

Many other advantages and features of the present invention will become manifest to those versed in the art upon making reference to the detailed description and the accompanying sheets of drawings in which a preferred structural embodiment incorporating the principles of the present invention is shown by way of illustrative example.

### BRIEF DESCRIPTION OF THE DRAWINGS

FIG. 1 is a perspective view showing the heatsink device according to an embodiment of the present invention used along with a fan installed on a side.

FIG. 2 is a perspective exploded view showing the heatsink device of FIG. 1.

FIG. 3 is a perspective view showing the heatsink device of FIG. 1.

FIG. 4 is a perspective view showing the heatsink device according to another embodiment of the present invention.

FIG. 5 is a perspective view showing the fiber-like fins of the heatsink device of the present invention are woven into webs.

### DETAILED DESCRIPTION OF THE PREFERRED EMBODIMENT

The following descriptions are of exemplary embodiments only, and are not intended to limit the scope, applicability or configuration of the invention in any way. Rather, the following description provides a convenient illustration for implementing exemplary embodiments of the invention. Various changes to the described embodiments may be in the function and arrangement of the elements described without departing from the scope of the invention as set forth in the appended claims.

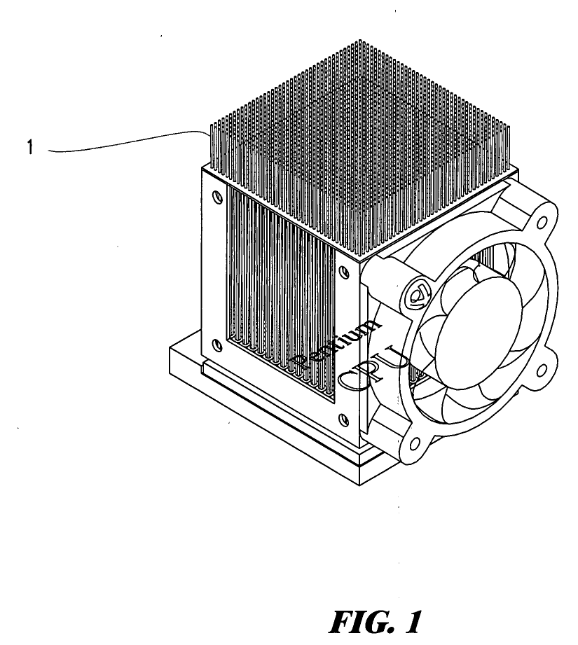

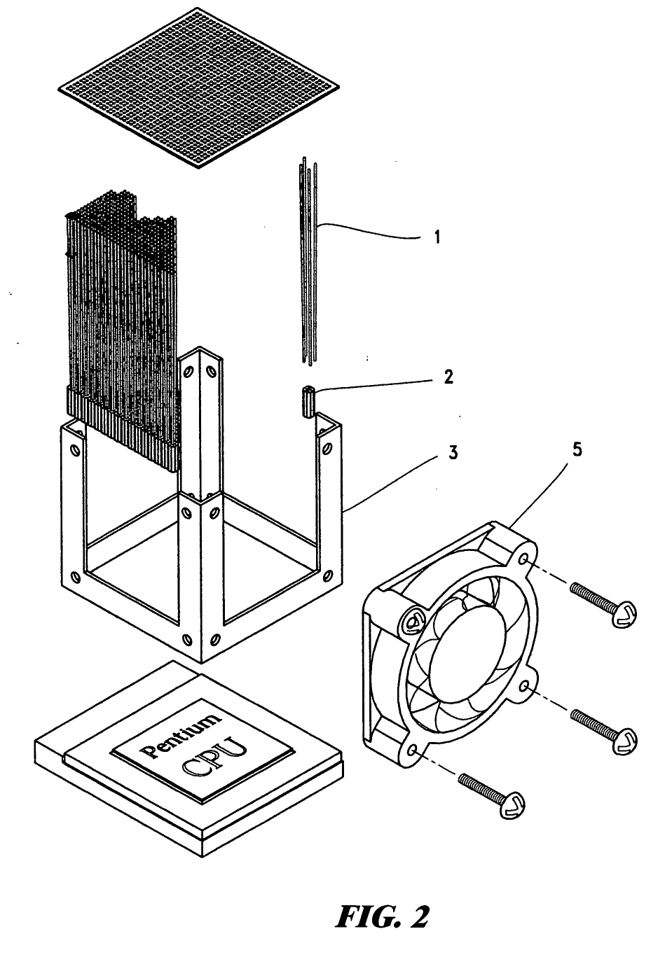

As illustrated in FIGS. 1 to 3, the heatsink device according to an embodiment of the present invention has a very large number of fins 1, each made by a highly thermal conducting material into a very thin fiber-like linear segment of 0.05˜0.2 mm in diameter. Every 3 to 5 fiber-like fins are supported together as a bundle by having one of their ends inserted into a tubular holder 2. All tubular holders 2 are welded or fused side by side to one another to form a planar base from which the fiber-like fins 1 extend vertically upward with appropriate spacing among the bundles.

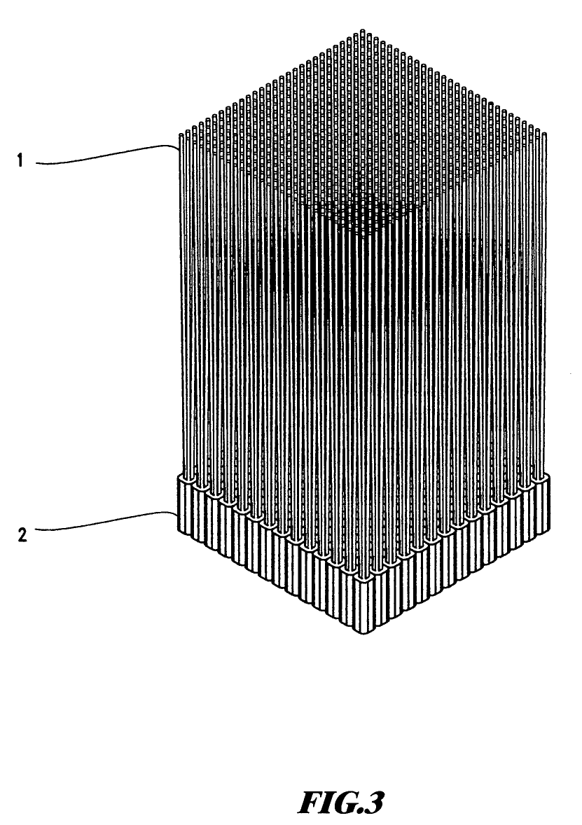

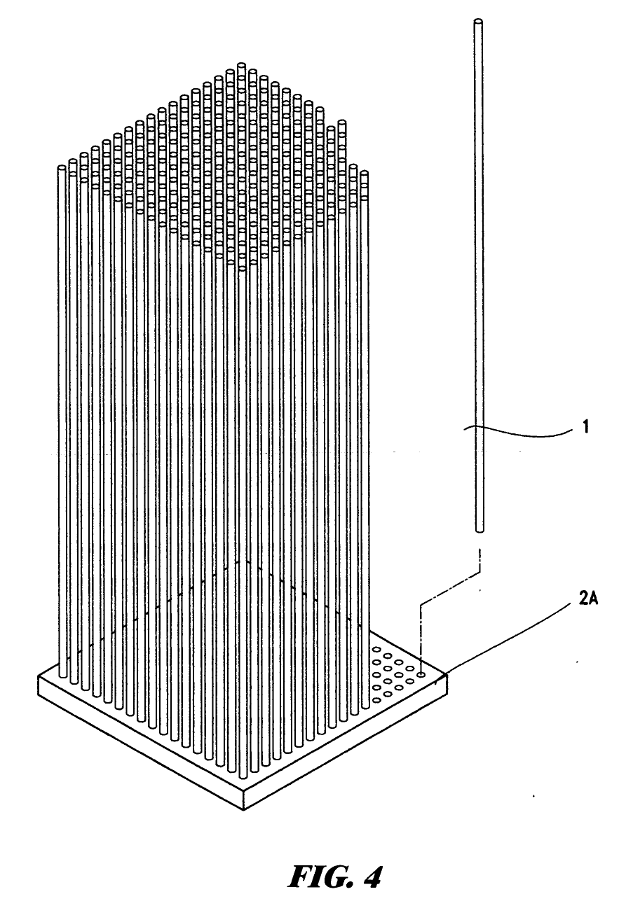

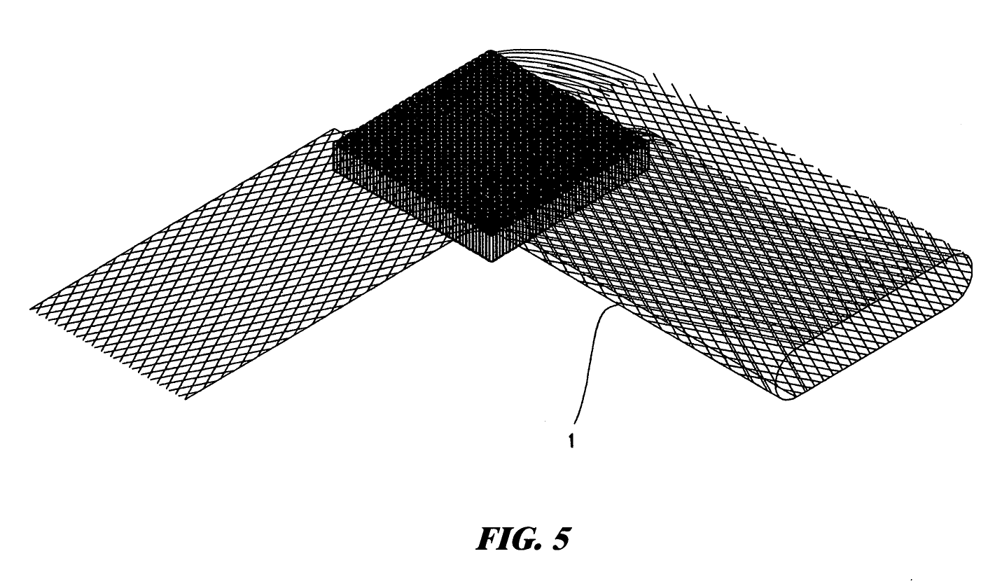

The heatsink device of FIG. 3 can directly installed on top of an IC chip and the heat from the IC chip is directly conducted to the fiber-like fins 1. as the fiber-like fins 1 have dramatically larger conger contact area with air than the conventional heatsink device, the heat is quickly dissipated. For IC chip producing significant amount of heat, the heatsink device can be configured inside a frame 3 where a fan 5 is provided on a side to enhance the cooling effect of the heatsink device. As shown in FIG. 4, another embodiment of the present invention has a planar base 2A with a large number of holes (not numbered) into which the fiber-like fins are inserted. As such, the fiber-like fins 1 extend vertically upward with appropriate spacing among them. When the heatsink device of the present invention has to be housed inside appliances having very limited or irregular interior space, as shown in FIG. 5, the fiber-like fins 1 can be bended and woven into webs to fit the special space limitation while maintaining superior heat dissipation efficiency.

It will be understood that each of the elements described above, or two or more together may also find a useful application in other types of methods differing from the type described above.

While certain novel features of this invention have been shown and described and are pointed out in the annexed claim, it is not intended to be limited to the details above, since it will be understood that various omissions, modifications, substitutions and changers in the forms and details of the device illustrated and in its operation can be made by those skilled in the art without departing in any way from the spirit of the present invention.

What is claimed is:

1. A heatsink device, comprising:
A plurality of tubular holders; and
a plurality of fins, each made of a thermal conducting material into a linear segment;
wherein every an appropriate number of said fins are supported together as a bundle by having one of their ends inserted into one of said tubular holder; and all of said tubular are joined together side by side to form a planar base from which said fins extend vertically upward with appropriate spacing among said bundles.

2. A heatsink device, comprising:
a planar base having a plurality of holes on the top surface; and
a plurality of fins, each made of a thermal conducting material into a linear-segment;
wherein each of said of fins, by having one of its ends inserted into one of said holes, extend vertically upward from said planar base with appropriate among said fins.

3. The heatsink device according to claim 1, wherein said fins are appropriately woven into at least a web.

4. The heatsink device according to claim 2, wherein said fins are appropriately woven into at least a web.
